(19) United States
(12) Patent Application Publication
(10) Pub. No.: US 2024/0359062 A1
(43) Pub. Date: Oct. 31, 2024

(54) Wireless Golf Ball Method of Manufacture

(71) Applicant: Graff Golf LLC, Sandy Springs, GA (US)

(72) Inventor: Eric Goodchild, Edmond, OK (US)

(73) Assignee: Graff Golf LLC, Sandy Springs, GA (US)

(21) Appl. No.: 18/140,545

(22) Filed: Apr. 27, 2023

(51) Int. Cl. A63B 43/00; A63B 37/00; B29D 99/00; H05K 3/28

(52) U.S. Cl. CPC A63B 43/004; A63B 37/0003; B29D 99/0042; H05K 3/284; A63B 2225/50; H02J 50/10

(57) ABSTRACT

A device and method for assembling an electronic golf ball are described. The device may include a printed circuit board, a wire wrapped around a ring-shaped bobbin, where the ring-shaped bobbin includes four legs, two on each side of the ring-shaped bobbin, with the printed circuit board inserted into the ring-shaped bobbin. This assembly, an electronic apparatus, is placed in a mold, with at least one of the four legs in contact with walls of the mold, the legs centering the electronic apparatus in a center of the mold. An inner layer material is inserted in the mold creating an inner core assembly. The inner layer assembly is removed from the mold and covered with a stiff spherical core and an outer golf ball cover layer, to form the golf ball.

### BACKGROUND

### Related Applications

This patent application is a priority patent application.

### Technical Field

The system, apparatuses, and methods described herein generally relate to golf balls and, in particular, to intelligent golf balls with a rechargeable power source.

### Description of the Related Art

Golf, as we know it today, originated from a game played on the eastern coast of Scotland in the Kingdom of Fife during the 15th century. Players would hit a pebble around a natural course of sand dunes, rabbit runs, and tracks using a stick or primitive club. Wooden golf balls were the first man-made golf balls, invented in the 1400s. These original wooden golf balls were inefficient at best and likely made of hardwoods such as Beech or Boxroot. The first “real” golf ball was known as a “feathery” golf ball. Basically, the feathery was a leather sack filled with boiled goose feathers, then stitched up and painted. These golf balls were used from the 1400s until the 1840s. In 1848, Rev. Dr. Robert Adams began creating golf balls out of Gutta Percha “Gutty”. The Gutty golf ball was created from the dried sap of the Sapodilla tree. It had a rubber-like feel and was formed into ball shapes by heating it up and shaping it while hot. It was soon discovered that dinged balls traveled further than new, smooth balls, and golf ball manufacturers added dimples to the golf balls.

In the late 1800s, the inside of the golf ball changed to a solid rubber core, high-tension rubber thread wrapped around the core, and a Gutta Percha cover. Various other cores were incorporated over the following years, with liquid, steel, lead, and glycerin used at various times. Today, two-piece solid Syrlin or Balata cover rubber cored balls are used. Recent rule changes (United States Golf Association (USGA)) for standard golf balls have allowed for balls with hollow steel spheres surrounded with rubber. With the improved designs in golf balls, the balls travel further. However, this means that the golf ball can travel further out of sight of the golfer and are more often lost than they were in the 1800s.

On average, most golfers lose four balls per round, adding a total of 20 minutes of play just searching for their ball. This means that tens of millions of golf balls are lost each year, leading to millions of dollars in extra costs to golfers. And the 20-minute delay in searching for lost golf balls slows down play on the course, leading to lost revenues for the country clubs.

There is a need for the technology of finding golf balls to catch up to the materials technology that has allowed for longer golf ball drives. The extreme number of lost golf balls creates a significant problem for golfers both in terms of cost and the inability of golfers to analyze their round. Golf balls can easily be lost in bushes and trees. They give the golfer no easy way to track golf ball movements and statistics.

There is a need for technology inside the balls to allow them to be found quickly. However, each golf ball may undergo 15,000 G's of force when the golf club hits the ball. Off of the club, the ball may spin at 9000 RPMs and travel at 180 miles per hour, so the technology must be hardened to the extreme physical forces. There is also a need for a software application to give a golfer helpful analytical data.

By placing electronics inside a golf ball, a method for providing power to the electronics needs to be solved. Batteries could be used, but have a limited shelf life, shorter than the typical life of a golf ball. The inventions described herein solve this problem with a wireless golf ball charging apparatus.

### BRIEF SUMMARY OF THE INVENTION

In some aspects, the techniques described herein relate to a method for manufacturing a golf ball including: assembling a printed circuit board; wrapping wire around a ring-shaped bobbin, where the ring-shaped bobbin includes four legs, two on each side of the ring-shaped bobbin; inserting the printed circuit board into the ring-shaped bobbin, creating an electronic apparatus; placing the electronic apparatus in a mold, with at least one of the four legs in contact with walls of the mold, the legs centering the electronic apparatus in a center of the mold; inserting an inner layer material in the mold creating an inner core assembly; and removing the inner core assembly from the mold.

In some aspects, the techniques described herein relate to a method for manufacturing the golf ball where the four legs of the ring-shaped bobbin attach to sides of the ring-shaped bobbin with two legs on each side, offset from each other by 180 degrees on the ring-shaped bobbin.

In some aspects, the techniques described herein relate to a method for manufacturing the golf ball where the four legs of the ring-shaped bobbin attach to sides of the ring-shaped bobbin with two legs on each side, the legs on each side offset by 90 degrees from an opposing side.

In some aspects, the techniques described herein relate to a method for manufacturing the golf ball where a top side of the four legs is curved at a radius that conforms to the radius of the mold.

In some aspects, the techniques described herein relate to a method for manufacturing the golf ball further including attaching a battery to the printed circuit board.

In some aspects, the techniques described herein relate to a method for manufacturing the golf ball further including using low pressure and controlled viscosity molding to insert the inner layer material in the mold.

In some aspects, the techniques described herein relate to a method for manufacturing the golf ball further including using injection molding to insert the inner layer material in the mold.

In some aspects, the techniques described herein relate to a method for manufacturing the golf ball where the inner layer material is a two-part resin.

In some aspects, the techniques described herein relate to a method for manufacturing the golf ball where the inner layer material is a polymer urethane visco-elastic material.

In some aspects, the techniques described herein relate to a method for manufacturing the golf ball further including inserting the inner core assembly in a second mold with a dimpled shape and injection molding a polymer into the second mold.

In some aspects, the techniques described herein relate to a golf ball apparatus including: a ring-shaped bobbin with four legs, two on each side of the ring-shaped bobbin, the ring-shaped bobbin having a trough on an outer side, the trough including wire wrapped around the ring-shaped bobbin; a printed circuit board, inserted in a middle of the ring-shaped bobbin, the printed circuit board including electronic components electrically connected to the wire; and a spherical-shaped inner layer of material surrounding the ring-shaped bobbin and the printed circuit board, a curved surface of the spherical-shaped inner layer including an outer surface of each leg.

In some aspects, the techniques described herein relate to a golf ball apparatus where the four legs of the ring-shaped bobbin attach to the sides of the ring-shaped bobbin with two legs on each side, offset from each other by 180 degrees on the ring-shaped bobbin.

In some aspects, the techniques described herein relate to a golf ball apparatus where the four legs of the ring-shaped bobbin attach to the sides of the ring-shaped bobbin with two legs on each side, the legs on each side offset by 90 degrees from an opposing side.

In some aspects, the techniques described herein relate to a golf ball apparatus where the top side of the four legs is curved at a radius that conforms to the radius of the spherical-shaped inner layer.

In some aspects, the techniques described herein relate to a golf ball apparatus further including a battery electrically and mechanically connected to the printed circuit board.

In some aspects, the techniques described herein relate to a golf ball apparatus further including a stiff spherical core surrounding the spherical-shaped inner layer.

In some aspects, the techniques described herein relate to a golf ball apparatus where the stiff spherical core includes a polymer matrix composite.

In some aspects, the techniques described herein relate to a golf ball apparatus further including a cover layer surrounding the stiff spherical core.

In some aspects, the techniques described herein relate to a golf ball apparatus where the cover layer includes a polymer.

In some aspects, the techniques described herein relate to a golf ball apparatus where the cover layer is dimpled.

### BRIEF DESCRIPTION OF THE DRAWINGS

FIG. 1 is a perspective view of the electronics and the charging apparatus inside of a golf ball.

FIG. 2 is a perspective view of a cut-away of the interior core of a golf ball with the electronics and the charging apparatus.

FIG. 3A is a side view cross-section of the interior core of a golf ball with the electronics and the charging apparatus.

FIG. 3B is a side view, 90° offset from FIG. 3A, cross-section of the interior core of a golf ball with the electronics and the charging apparatus.

FIG. 4 is a perspective cutaway view of the golf ball showing the electronics and the charging apparatus.

### DETAILED DESCRIPTION

The present inventions describe several embodiments for charging the electronics in a golf ball, where the golf ball includes hardened electronics designed to handle the extreme forces that occur when the ball is hit by the club. See U.S. patent application Ser. No. 17/472,595, “Wireless Golf Ball Charging Apparatus”, filed on Sep. 11, 2021, by the Applicant, hereby incorporated by reference in its entirety, for more details on the electronics related to the charging of the golf ball.

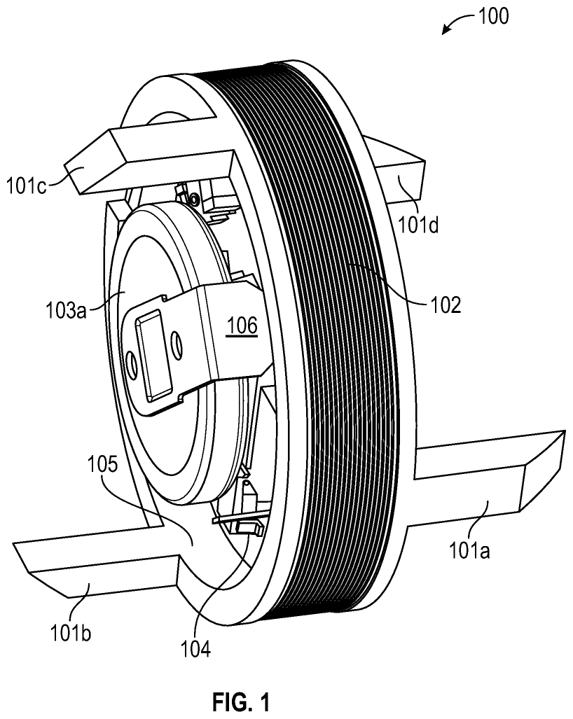

FIG. 1 shows the electronic components and charging apparatus 100 of the wireless golf ball. The electronic components on the printed circuit board 104 can be seen underneath the battery 103a and the battery holder 106. The printed circuit board 104 is enclosed (in the middle) in a bobbin 105. The bobbin 105 is ring-shaped and may have a trough on the outer side. In some embodiments, the inner and outer side of the bobbin 105 is flat. The bobbin 105 holds the coil 102 of wire for receiving the wireless power. The bobbin 105 could be made of ABS, other plastics, cardboard, wood, or other materials. In some embodiments, the bobbin 105 is made of the same material as the inner layer 201 so that when the inner layer is added, the bobbin 105 becomes integral with the inner layer 201. In some embodiments, the bobbin 105 is injection molded, in others, it is milled to shape, and in still other embodiments, the bobbin 105 is 3D printed, or any combination thereof.

The bobbin 105 has two walls on either side of the coil area. In some embodiments, the internal diameter of the bobbin 105 is 22.00 mm and the width is 5.6 mm. The inner width is 4.00 mm in the coil area, where the coil 102 is located. In some embodiments, one of the walls has a gap to allow the wire to leave the coil area. In some embodiments, the walls of the bobbin 105 are 0.80 mm thick and 0.30 mm high. The gap could be 2 mm wide and 0.30 mm deep.

The bobbin 105 includes four centering legs 101a, 101b, 101c, 101d on the walls of the bobbin, extending at a right angle from the wall, in some embodiments. The four centering legs 101a, 101b, 101c, 101d could be oval, square, or rectangular at their cross-section. In some embodiments, the outer side of the centering legs 101a, 101b, 101c, 101d are curved to conform with the radius of the outer edge of the bobbin 105. The inner side of the centering legs 101a, 101b, 101c, 101d could conform with the radius of the inner edge of the bobbin 105. The top of the centering legs 101a, 101b, 101c, 101d could be at an angle to the bobbin 105 and could have a radius that conforms to the radius of the inner layer 201 of the golf ball. The radius of the inner layer 201 of the golf ball also matches the inner radius of the mold. The inner layer 201 may be spherical in shape.

The four centering legs 101a, 101b, 101c, 101d attach to the sides of the bobbin 105 with two on each side, offset by 180 degrees, and each side offset by 90 degrees on each side, offset by 180 degrees, and each side offset by 90 degrees. As seen in FIG. 1, centering leg 101b and centering leg 101c are on the same side of the bobbin 105, and are positioned 180 degrees offset from each other. Centering leg 101a and centering leg 101d are on the opposing side of the bobbin 105. Centering leg 101a and centering leg 101d are positioned 180 degrees offset from each other, and the pair of centering legs 101a, 101d are offset from the pair of centering legs 101b, 101c by 90 degrees.

The positioning of the centering legs 101a, 101b, 101c, 101d allows the electronic components and charging apparatus 100 to be centered in a mold so that the inner layer 201 material can be injected to encase the electronic components and charging apparatus 100. At least one, and perhaps all four centering legs 101a, 101b, 101c, 101d are in contact with the walls of the mold.

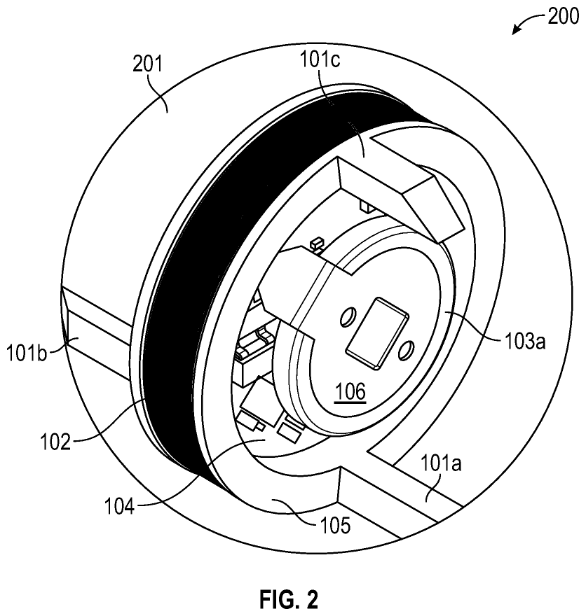

Looking at FIG. 2, we see the inner layer 201 surrounding the electronic components and charging apparatus 100, formed into a spherical core 200. The four centering legs 101a, 101b, 101c, 101d extend to the edge of the inner layer 201, centering the electronic components and charging apparatus 100 in the center of the inner layer 201.

The inner layer 201 could be made of a two-part resin, a polymer urethane visco-elastic material, Silicone, Neoprene, Norsorex, Rubber, Deflex, Gel-mec, Microsorb, Memory foam, Acoustic foam, plastic, or other similar material. The polymer urethane visco-elastic material could be Sorbathane to absorb the impact of the golf club striking the golf ball. Sorbothane is described in a series of patents awarded to Dr. Maurice Hiles, including U.S. Pat. Nos. 4,101,704, 4,346,205, 4,476,258, and 4,808,469.

The manufacturing method is as follows. To manufacture the golf ball, the electronic components and charging apparatus 100 are assembled with the four centering legs 101a, 101b, 101c, 101d. This may include populating the printed circuit board 104 with the electrical components and winding the wire 102 around the bobbin 105. The ends of the wire 102 may be soldered to the printed circuit board 104. In another embodiment, the wire may have a connector that connects to a connector on the printed circuit board. In still another embodiment, the wire and the PC board are incorporated into a single flex printed circuit board that may wrap around the bobbin 105 or be incorporated into the bobbin 105.

The batteries 103a (and 103b in some embodiments) are mounted on the printed circuit board 104 inside of the battery holder 106. The electronic components and charging apparatus 100 are placed in a spherical mold where the centering legs 101a, 101b, 101c, 101d touch (are in contact with) the walls of the mold, keeping the electronic components and charging apparatus 100 at the center of the mold. The inner layer 201 material is then inserted in the mold to surround the electronic components and charging apparatus 100.

In some processes, the inner layer 201 could be injection molded around the electronic components and charging apparatus 100. In another embodiment, low-pressure and controlled viscosity molding may be used to cover the electronic components and charging apparatus 100 with the inner layer 201 material. See U.S. Pat. No. 9,931,773 and related patents, for more information regarding this process.

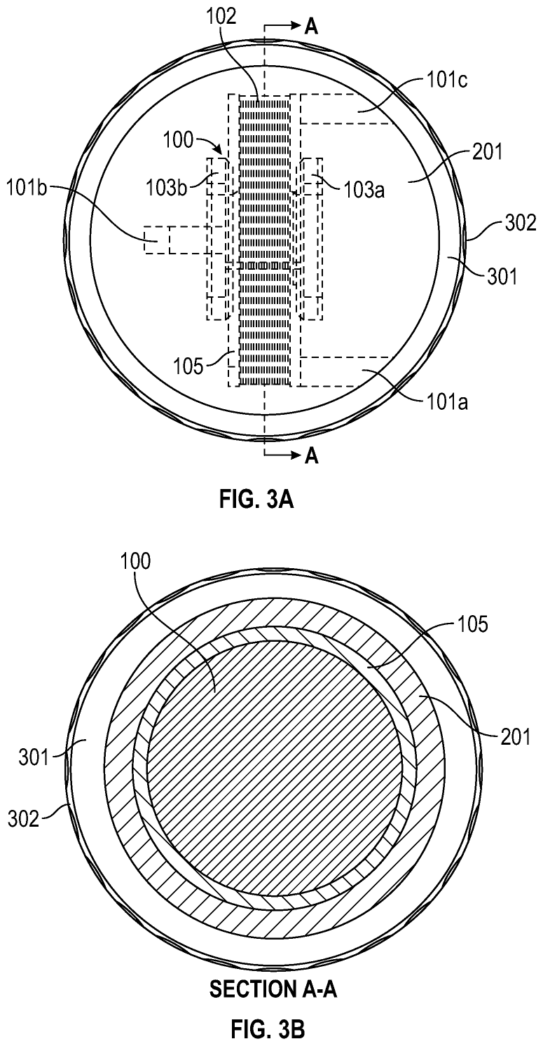

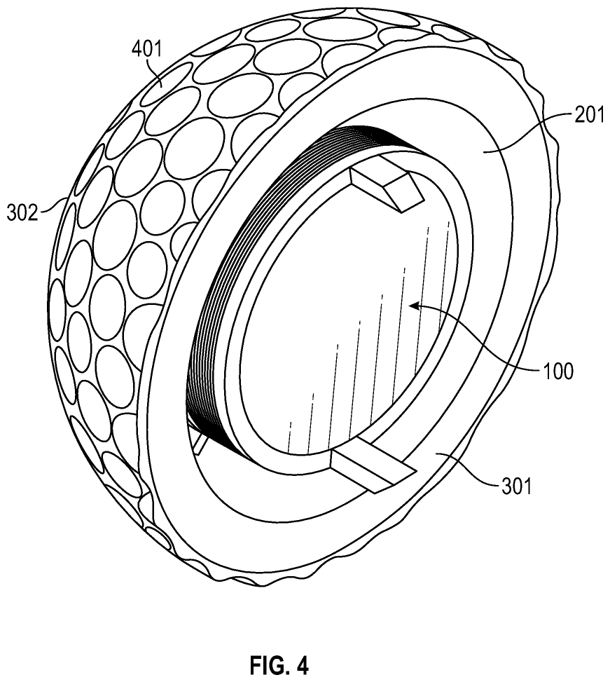

In FIGS. 3A, 3B, and 4, the outer layers of the golf ball can be seen. The process to assemble the golf ball continues, the inner layer 201 is removed from the mold, clayed with a rubber-like polybutadiene, and then compression molded to form the spherical core 301. After the spherical core 301 is formed, a third and sometimes fourth thin layer of harder plastic may be added. The final layer, the cover layer 302 having a dimple pattern formed by a compression mold. In another embodiment, the process is also done with a molding process (perhaps injection molding), but with a very specific time sequence with pins that hold that ball in the center of the mold until the plastic is hard enough to hold the ball in the center but still soft enough to fill in the areas where the pin retracted.

FIG. 3A shows a side view of a cross-section of the golf ball. The electronic components and charging apparatus 100 is seen with the bobbin 105, its coil 102 of wire, and the batteries 103a, 103b. The electronic components and charging apparatus 100 is encased in the inner layer 201. The three of the four centering legs 101a, 101b, 101c, 101d can be seen, centering the electronic components and charging apparatus 100 in the inner layer 201.

The inner layer 201 is surrounded by a stiff spherical core 301. The spherical core 301 is surrounded by cover layer 302 that includes dimples or other surface features that are known in the art to improve flight characteristics. The cover layer 302 defines a cover thickness, which is about 4 mm, but may be any thickness between about 1 mm and about 6 mm, including all values and ranges in-between. The cover layer 302 with the surface dimple pattern could be made of a polymer sold under the trade name SURLYN® (manufactured by DuPont). In another example, the cover layer 302 is made of an ionomer, urethane, balata, polybutadiene, other synthetic elastomers, or any other material suitable for a golf ball cover. The cover layer 302 also forms the golf ball's diameter. In one embodiment, the golf ball diameter is approximately 42.67 mm (1.68 inches) but may be any diameter equal to, greater than, or less than 42.67 mm that is capable of play. For example, USGA-legal golf balls are 1.68 inches (42.67 mm) or greater in diameter. For example, the golf ball diameter may be between about 40 mm and about 45 mm, including all values and ranges in between.

The spherical core 301 is a rubber-like polybutadiene, a polymer matrix composite, metal matrix composite, or carbon matrix composite. The diameter of the spherical core 301 may be any diameter from about 10 mm (0.39 inches) to about 42 mm (1.60 inches), including all values and ranges in between.

For more details of the golf ball construction, see U.S. Pat. No. 10,864,410, “Bluetooth enabled ball analyzer and locator”, issued to Michael Eberle, Patrick Kelly, and Aaron Shapiro, said patent incorporated herein by reference.

FIG. 3B shows a side cross-section of the golf ball, offset 90 degrees from the view in FIG. 3A. The cover layer 302 is seen on the outside, encasing the spherical core 301. The spherical core 301 encases the inner layer 201. The inner layer 201 encases the bobbin 105 and the rest of the electronic components and charging apparatus 100.

FIG. 4 offers a perspective cross-section view of the golf ball. The electronic components and charging apparatus 100 is seen at the center with two of the four centering legs 101a, 101b, 101c, 101d used to center the electronic components and charging apparatus 100 in the inner layer 201. The inner layer 201 is encased in the spherical core 301. The spherical core 301 is covered by the cover layer 302. The golf ball dimples 401 can be seen in the cover layer 302

The foregoing devices and operations, including their implementation, will be familiar to, and understood by, those having ordinary skill in the art. All sizes used in this description could be scaled up or down without impacting the scope of these inventions. All dimensions in the figures or descriptions are used to show one possible embodiment. Other dimensions may be used without deviating from the inventions herein.

The above description of the embodiments, alternative embodiments, and specific examples, are given by way of illustration and should not be viewed as limiting. Further, many changes and modifications within the scope of the present embodiments may be made without departing from the spirit thereof, and the present invention includes such changes and modifications.

1. A method for manufacturing a golf ball comprising:
assembling a printed circuit board;
wrapping wire around a ring-shaped bobbin, where the ring-shaped bobbin includes four legs, two on each side of the ring-shaped bobbin;
inserting the printed circuit board into the ring-shaped bobbin, creating an electronic apparatus;
placing the electronic apparatus in a mold, with at least one of the four legs in contact with walls of the mold, the legs centering the electronic apparatus in a center of the mold;
inserting an inner layer material in the mold creating an inner core assembly; and
removing the inner core assembly from the mold.

2. The method for manufacturing the golf ball of claim 1 where the four legs of the ring-shaped bobbin attach to sides of the ring-shaped bobbin with two legs on each side, offset from each other by 180 degrees on the ring-shaped bobbin.

3. The method for manufacturing the golf ball of claim 1 where the four legs of the ring-shaped bobbin attach to sides of the ring-shaped bobbin with two legs on each side, the legs on each side offset by 90 degrees from an opposing side.

4. The method for manufacturing the golf ball of claim 1 where a top side of the four legs is curved at a radius that conforms to the radius of the mold.

5. The method for manufacturing the golf ball of claim 1 further comprising attaching a battery to the printed circuit board.

6. The method for manufacturing the golf ball of claim 1 further comprising using low pressure and controlled viscosity molding to insert the inner layer material in the mold.

7. The method for manufacturing the golf ball of claim 1 further comprising using injection molding to insert the inner layer material in the mold.

8. The method for manufacturing the golf ball of claim 1 where the inner layer material is a two-part resin.

9. The method for manufacturing the golf ball of claim 1 where the inner layer material is a polymer urethane visco-elastic material.

10. The method for manufacturing the golf ball of claim 1 further comprising inserting the inner core assembly in a second mold with a dimpled shape and injection molding a polymer into the second mold.

11. A golf ball apparatus comprising:
a ring-shaped bobbin with four legs, two on each side of the ring-shaped bobbin, the ring-shaped bobbin having a trough on an outer side, the trough including wire wrapped around the ring-shaped bobbin;
a printed circuit board, inserted in a middle of the ring-shaped bobbin, the printed circuit board including electronic components electrically connected to the wire; and
a spherical-shaped inner layer of material surrounding the ring-shaped bobbin and the printed circuit board, a curved surface of the spherical-shaped inner layer including an outer surface of each leg.

12. The golf ball apparatus of claim 11 where the four legs of the ring-shaped bobbin attach to sides of the ring-shaped bobbin with two legs on each side, offset from each other by 180 degrees on the ring-shaped bobbin.

13. The golf ball apparatus of claim 11 where the four legs of the ring-shaped bobbin attach to sides of the ring-shaped bobbin with two legs on each side, the legs on each side offset by 90 degrees from an opposing side.

14. The golf ball apparatus of claim 11 where a top side of the four legs is curved at a radius that conforms to the radius of the spherical-shaped inner layer.

15. The golf ball apparatus of claim 11 further comprising a battery electrically and mechanically connected to the printed circuit board.

16. The golf ball apparatus of claim 11 further comprising a stiff spherical core surrounding the spherical-shaped inner layer.

17. The golf ball apparatus of claim 16 where the stiff spherical core comprises a polymer matrix composite.

18. The golf ball apparatus of claim 17 further comprising a cover layer surrounding the stiff spherical core.

19. The golf ball apparatus of claim 18 where the cover layer comprises a polymer.

20. The golf ball apparatus of claim 18 where the cover layer is dimpled.
